(19) United States
(12) Patent Application Publication
(10) Pub. No.: US 2026/0223288 A1
(43) Pub. Date: Jul. 30, 2026

(54) Glass Barrier Layer Product, and Manufacture Method

(71) Applicant: AT&S Austria Technologie & Systemtechnik Aktiengesellschaft, Leoben (AT)

(72) Inventors: Anna Lucy DE LOS SANTOS, Leoben (AT); Daniel SCHLICK, St. Marein-Feistritz (AT); Walter PESSL, Leoben (AT); Marie SCALBERT, Leoben (AT); Erich SCHLAFFER, St. Lorenzen (AT); Hiroaki TAKAHASHI, Vienna (AT); Heinrich TRISCHLER, Eggersdorf (AT)

(21) Appl. No.: 19/141,387

(22) PCT Filed: Dec. 21, 2023
(86) PCT No.: PCT/EP2023/087492

§ 371 Date: Jun. 20, 2025

(30) Foreign Application Priority Data
Dec. 22, 2022 (EP) 22306993.1

(51) Int. Cl. H05K 1/03; H05K 1/11; H05K 3/00; H05K 3/38; H05K 3/46

(52) U.S. Cl. CPC H05K 1/0306; H05K 1/119; H05K 3/0067; H05K 3/381; H05K 3/4605; H05K 3/467; H05K 3/4697; H05K 2201/017; H05K 2203/095

(57) ABSTRACT

A product, in particular a component carrier, including: i) an electrically insulating layer structure; ii) an electrically conductive layer structure; and iii) at least one glass barrier layer, at least partially sandwiched between the electrically insulating layer structure and the electrically conductive layer structure. The at least one glass barrier layer has two main surfaces. The two main surfaces have a different adhesion property. Further, a manufacturing method is described.

### CROSS REFERENCE TO RELATED APPLICATIONS

This application is a national stage application, filed under 35 U.S.C. § 371, of International Patent Application No. PCT/EP2023/087492, filed on Dec. 21, 2023, claiming priority of the filing date of the Patent Application No. 22306993.1, filed on Dec. 22, 2022, with the European Patent Office, the disclosures of which are hereby incorporated by reference herein in their entirety.

### TECHNICAL FIELD

The disclosure relates to a product, in particular a component carrier such as a printed circuit board or an IC substrate, with an electrically conductive layer structure, an electrically insulating layer structure, and a glass barrier layer.

Further, the disclosure relates to a method of manufacturing the product, and to a use of a silane and/or siloxane layer.

### TECHNICAL BACKGROUND

In the context of growing product functionalities of component carriers equipped with one or more electronic components and increasing miniaturization of such electronic components as well as a rising number of electronic components to be mounted on the component carriers such as printed circuit boards, increasingly more powerful array-like components or packages having several electronic components are being employed, which have a plurality of contacts or connections, with ever smaller spacing between these contacts. Removal of heat generated by such electronic components and the component carrier itself during operation becomes an increasing issue. Also, an efficient protection against electromagnetic interference (EMI) becomes an increasing issue. At the same time, component carriers shall be mechanically robust and electrically and magnetically reliable so as to be operable even under harsh conditions.

In particular, providing an efficient and robust adhesion between an electrically insulating layer and an electrically conductive layer may still be seen as a major challenge.

This issue may in particular arise in the economically important step of laminating a metal (e.g. copper) layer together with a dielectric layer (e.g. a prepreg). In order to establish a sufficient adhesion, the metal surface is conventionally roughened (e.g. by micro-etching, for example to a micro roughness in the range of Ra=0.5 μm to 1.5 μm) to provide a larger surface and hence improved adhesion.

This measure has, however, the drawback that rough metal surfaces tend to show the so-called skin-effect, leading to current losses, and thereby decreasing the quality of a signal, in particular of a high-frequency signal (e.g. above 2 GHz). As a consequence, in particular in the field of high-frequency signal transmission, a smooth metal surface may be preferred.

In a conventional example, to fulfill the requirement of smooth metal structures in combination with a robust adhesion to the dielectric layer, smooth copper foils with improved organic adhesion promoters and/or coating with silane/siloxane adhesion promoters can be applied. Generally, silane/siloxane adhesion promoters for component carriers are silane or siloxane monomolecular layers that are deposited by wet chemical dipping processes.

In a further example, silanes or siloxanes are used as an adhesion layer between a metal layer and a dielectric layer, or between two dielectric layers. In this case, the silane/siloxane layer is conventionally deposited by sputtering, e.g. chemical vapor deposition (CVD). Nevertheless, this method may be considered cumbersome and economically costly.

### SUMMARY

There may be a need to provide an efficient and robust adhesion between an electrically insulating layer and an electrically conductive layer.

A product, a manufacturing method, and a use are provided.

According to a first embodiment of the disclosure, there is described a (electronic) product (in particular a component carrier such as a printed circuit board or an IC substrate), comprising: i) an electrically insulating layer structure (e.g. a dielectric, in particular a resin layer) (at least two layers); ii) an electrically conductive layer structure (e.g. a metal layer); and iii) at least one glass barrier layer (in other words: a barrier layer, a silane/siloxane layer, etc.), at least partially sandwiched between the electrically insulating layer structure and the electrically conductive layer structure. The at least one glass barrier layer comprises two main surfaces, wherein the two main surfaces comprise a different adhesion property (for example a different surface tension (property)) (with respect to each other).

According to a second embodiment of the disclosure, there is described a method (of manufacturing a product), comprising: i) forming an electrically insulating layer structure; ii) forming an electrically conductive layer structure; and iii) forming a glass barrier layer in between the electrically insulating layer structure and the electrically conductive layer structure. Hereby, the at least one glass barrier layer comprises two main surfaces, wherein the two main surfaces comprise a different adhesion property.

According to a third embodiment of the disclosure, there is described a use of (method of using) a silane and/or siloxane layer between an electrically insulating layer structure and an electrically conductive layer structure as a (gas) barrier layer and/or adhesion promoter.

### OVERVIEW OF EMBODIMENTS

In the context of the present document, the term “glass barrier layer” may in particular refer to a layer (structure) that comprises glass material and is, at the same time, suitable to fulfill a barrier function, in particular regarding the migration of chemical species. In this context, the term “glass” may in particular refer to a non-crystalline and amorphous solid. In a preferred example, the glass comprises silicate, in particular silicon dioxide (SiO₂). In a further example, the glass comprises at least one silane and/or siloxane compound. In yet another example, the glass may comprise functional groups, e.g. hydrophilic and/or hydrophobic functional groups, in particular at the main surfaces. Since the glass barrier layer is a (continuous or discontinuous) layer, it comprises two main surfaces opposite to each other. Hereby, the two main surfaces can be different in at least one physical/chemical property, specifically regarding their surface tension (surface energy).

In the context of the present document, the term “adhesion property” may in particular refer to the tendency of (dissimilar) particles/surfaces to stick together. An adhesion property may for example be the hydrophilicity or hydrophobicity of a surface. A further adhesion property may be the surface tension or the wettability of a surface. These adhesion properties may overlap with each other. The adhesion property can be imparted through the provision of a functional group on the specific surface.

In the context of the present document, the term “surface tension” may refer to a description of the physical interaction between the surfaces, in particular the surfaces in direct contact, of two substances. The surface tension may be measured as the force per unit length (N/m) or of energy per unit area (J/m²). Even though the term “surface tension” generally refers to liquids and the term “surface energy” would refer to the equivalent property of solids, these terms may be used synonymously in the present context, specifically because the glass of the glass barrier layer may be either seen as a liquid or a solid (chemically, glass is considered as an undercooled liquid).

The surface tension (properties) may be directly linked to the wettability of a surface. For example, the difference in the surface tension of the two main surfaces may be directly seen in a different surface wettability. In an illustrative example, the first main surface may comprise rather hydrophilic properties, while the second main surface may comprise hydrophobic properties. In another example, both main surfaces may comprise hydrophilic properties, yet being different from each other. Yet in another example, both main surfaces may comprise hydrophobic properties, yet being different from each other.

In the context of the present document, the term “component carrier” may particularly denote any support structure which is capable of accommodating one or more components thereon and/or therein for providing mechanical support and/or electrical connectivity. In other words, a component carrier may be configured as a mechanical and/or electronic carrier for components. In particular, a component carrier may be one of a printed circuit board, an organic interposer, a metal core substrate, an inorganic substrate and an IC (integrated circuit) substrate.

In the context of the present document, the term “IC substrate” may particularly denote a small component carrier. An IC substrate may be a, in relation to a PCB, comparably small component carrier onto which one or more components may be mounted and that may act as a connection medium between one or more chip(s) and a further PCB. More specifically, an IC substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. In an example, an IC substrate may be seen as an interposer, for example between electronic components and a printed circuit board.

In the present context, an IC substrate should not be understood as only any substrate suitable to bear an IC. Instead, the term “IC substrate” may be a technically established term for a specific, high-density PCB that comprises common PCB materials.

According to an example embodiment, the disclosure may be based on the idea that an efficient and robust adhesion between an electrically conductive layer structure and an electrically insulating layer structure may be achieved, when a glass barrier layer is sandwiched between said two layer structures, and wherein the glass barrier layer comprises two main surfaces with a different adhesion property (e.g. surface tension (in particular a different wettability)).

While not wishing to be bound to a specific theory, it is believed that the migration of a chemical species, such as oxygen from air or moisture, in the resin material is one of the reasons for the long-and short-term failures of adhesion between a metal and a dielectric. The failure of adhesion of metal to dielectric materials may thus have its origin in the migration of chemical species such as oxygen and/or moisture etc. ions, which may ultimately result in the oxidation of the metal surface, followed by catalytic reactions of formed metal oxides and other substances (eventually also with an adhesion promoter).

Conventional silane or siloxane adhesion promoters for component carriers are generally silane or siloxane monomolecular layers that are deposited by chemical wet processes, e.g. chemical dipping processes, or physical deposition processes, e.g. sputtering, which are therefore not acting as a barrier layer to block chemical substance migration towards the metal surface. Instead, these layers may themselves cause metal corrosion as well as delamination of dielectric material from the metal surface.

It has now been found by the inventors that a glass barrier layer may be applied with a highly efficient and robust adhesion result when the glass barrier layer comprises different physical/chemical properties (in particular regarding the adhesion) at its opposite two main surfaces, one of them being optimized for the metal layer structure, while the other one is optimized for the dielectric layer structure. In an example, the main surface in contact with the dielectric layer structure may be rather hydrophobic, while the main surface in contact with the metal layer structure may be rather hydrophilic.

With the described approach, there may be two advantages achieved at the same time: i) a strong adhesion between the electrically conductive layer structure and the electrically insulating layer structure is enabled via the glass barrier layer, and ii) an efficient barrier layer is established to prevent migration of chemical species, thereby enabling the provision of an efficient and robust component carrier product also in the long term.

Further, a high-frequency signal application and/or fine line applications may be significantly improved by the described approach, in particular because smooth metal surfaces can be applied. Additionally, adhesion promoting processes, e.g. bond-film process for inner layers, may be replaced as well as micro-etching processes for outer layers.

In an embodiment, without wishing to be bound to a specific theory, the glass barrier layer may prevent copper from reacting (catalytically, in particular at elevated temperatures >70° C.). This may prevent detaching of one copper structure with the dielectric structure, in particular breaking chemical bonds between these structures. In this way, it may be possible to reliably attach a similar or a different material to a surface with a very smooth roughness of e.g. 5 nm or smaller. In an example, a pattern of fine line metal, in particular copper, traces may be reliably connected/attached to an electrically insulating material.

### EXAMPLE EMBODIMENTS

According to an embodiment, the different adhesion property comprises a different surface tension. Thereby, a different adhesion property may be realized in an efficient manner (see description above).

According to a further embodiment, the different adhesion property comprises functional groups at only one of the two main surfaces. According to a further embodiment, the different adhesion property comprises (different) functional groups at both of the two main surfaces (with respect to each other). Examples of functional groups are given further below.

According to a further embodiment, the at least one glass barrier layer is configured to suppress migration of chemical species (comprising at least one atom) between the electrically insulating layer structure and the electrically conductive layer structure. As explained above, migration of chemical species, such as ions (in particular oxygen ions), may alter the adhesion between a metal layer and a dielectric layer, e.g. by oxidizing the metal layer.

As a consequence, the suppression of migration, caused by the barrier layer, may significantly improve the adhesion between the electrically conductive layer structure and the electrically insulating layer structure.

In an example, the chemical species may comprise one of oxygen, a halide ion, and water (in particular in form of moisture).

According to a further embodiment, the at least one glass barrier layer comprises a thickness in the range 10 nm to 600 nm, in particular 50 nm to 350 nm. This may provide the advantage that the barrier layer can be provided as an extremely thin layer that still efficiently fulfills its positive effects.

According to a further embodiment, the electrically conductive layer structure comprises at least one rough surface, in particular with a surface roughness Ra of 0.5 μm or larger, in particular 2 μm or larger, more in particular in the range 2 to 5 μm.

According to a further embodiment the at least one glass barrier layer comprises at least one rough surface, in particular at least where the electrically conductive layer structure is in contact with the glass barrier layer.

According to a further embodiment, the electrically conductive layer structure comprises at least one smooth surface, in particular with a surface roughness Ra of 200 nm or smaller, more in particular 150 nm or smaller, more in particular 100 nm or smaller, more in particular 90 nm or smaller.

This may provide the advantage that a smooth metal layer surface may be provided, while the adhesion to the dielectric layer (via the glass barrier layer) is still robust and reliable. Providing a smooth metal layer surface further provides the advantage that the skin effect (which occurs in rough surfaces) is suppressed, so that high frequency signal transportation may be improved. Additionally, the smooth metal surface may enable a fine-line structuring.

A general parameter to quantify a fine-line structuring (high density pattern) may be the line spacing (L/S), i.e. the compared lengths of metal traces and the dielectric material portions in between. The smaller the line spacing, the higher may be the density of a metal trace pattern. In an example, an L/S of 12/12 μm or lower (in particular 10/10 μm or lower, more in particular 5/5 μm or lower) may be technically especially advantageous, for example with respect to miniaturization and (signal) transmission quality.

According to a further embodiment, the at least one glass barrier layer comprises: i) a first layer (associated with the first main surface) being in direct (physical) contact with the electrically conductive layer structure; and/or ii) a second layer (associated with the second main surface) being in direct (physical) contact with the electrically insulating layer structure.

This may provide the advantage that the different properties (specifically regarding the surface tension) of the two main surfaces can be realized in a straightforward and easy-to-implement manner. In an example, both layers can be manufactured separately, each with its own properties. Then, both layers can be coupled, e.g. by lamination, or one layer can be deposited on top of the other layer, e.g. using a plasma process.

In another example, both layers can be manufactured in the same process, e.g. by providing different chemical reactions/functional groups to the respective different layers.

According to a further embodiment, at least one glass barrier layer comprising on one main surface a first hydrophilic property and/or functional groups (i.e. hydroxyl functional groups) which is/are in direct contact with an electrically conductive layer structure, in particular metal (e.g. copper), and on the opposed second main surface a second hydrophilic property or hydrophobic property and/or functional groups, which is/are in particular different to the first hydrophilic property and/or functional groups, (e.g. acrylate or VTMO (vinyltrimethoxysilane)) which is/are in direct contact with at least a portion of an electrically insulating layer structure, in particular dielectric material (i.e. organic material or glass). Thereby, the first and/or second main surface of the glass barrier layer comprising the first and/or the second hydrophilic property or hydrophobic property and/or functional groups may be varied in dependence of the surface properties of the electrically conductive or insulating layer structure.

This may result in a strong physical and/or chemical interaction between the surface of the electrically conductive layer structure and the first main surface of the glass barrier layer and the electrically insulating layer structure and the second main surfaces of the glass barrier layer.

According to a further embodiment, at least one glass barrier layer comprising on one main surface a hydrophilic property and/or functional groups (i.e. hydroxyl functional groups) which is/are in direct contact with an electrically conductive layer structure, in particular metal (e.g. copper), and on the opposed second main surface a hydrophobic property and/or functional groups (e.g. HDMSO (hexamethyldisiloxane)) which is/are in direct contact with at least part of an electrically insulating layer structure, in particular dielectric material (e.g. organic material or glass).

Accordingly, where the second main surface of the glass barrier layer is in direct contact with the electrically insulating layer structure, there may be weak and/or no physical and/or chemical interaction between the electrically conductive layer structure and at least part of the electrically insulating layer structure. In a preferred example, this technical feature may be used to create cavities in a (multilayer) stack in an easy and reliable way.

According to a further embodiment, one of the two main surfaces of the at least one glass barrier layer and/or the first layer comprises hydrophilic properties.

According to a further embodiment, the other one of the two main surfaces of the at least one glass barrier layer and/or the second layer comprises hydrophilic properties or hydrophobic properties.

This may provide the advantage that the two different main surfaces may be adjusted (and even optimized) for a direct physical contact with the electrically conductive layer structure and the electrically insulating layer structure, respectively. A metal layer and a dielectric layer are generally quite different in their physical/chemical properties, so that different surface tensions, enabling different hydrophilic/hydrophobic properties (and a different wettability), may be well suited to adjust an advantageous degree of adhesion.

According to a further embodiment, one of the two main surfaces of the at least one glass barrier layer and/or the first layer (and/or the second layer) comprises at least one functional group (at the silane/siloxane component) for providing the hydrophilic properties. Thereby, the hydrophilic properties may be provided in an efficient and selective manner.

Such hydrophilic properties may be achieved for example by one of the following functional groups: imine, amine, thiol, thioamide, phosphate, hydroxyl, thiazole, imidazole, acrylate, methacrylate, an alcohol group, in particular 3-hydroxypropyl or 2-hydroxyethyl. In an example, acrylate and methacrylate may be preferred silanes for the glass barrier layer. Alcohol groups to be included may in particular comprise 3-hydroxypropyl or 2-hydroxyethyl.

In an example, the first layer comprises a silane/siloxane containing nitrogen groups and/or silane/siloxanes in a mixture with molecules containing a nitrogen group such as 3-ureidopropyltriethoxysilane or siloxane, 3-aminopropyl)tiethoxysilan, trimethoxylsilylbenzotriazole, triallylisocyanurate, divinylbenzimidazole, diallylamine, vinylimidazole, or cyclic azasilane or siloxanes.

According to a further embodiment, the other one of the two main surfaces of the at least one glass barrier layer and/or the second layer comprises at least one functional group (at the silane/siloxane component) for providing the hydrophobic properties.

Such hydrophobic properties may be achieved for example by one of the following functional groups: epoxy, allyl, amine, vinyl, alkyl, anhydride, in particular maleic anhydride, furane, pyrrole, thiophene, and/or a cyclic unsaturated alkene, in particular cyclic pentene. In an example, preferred groups may include alkyl, allyl, vinyl, and a cycle unsaturated alkene.

In a further example, there is used a hydrophobic silane/siloxane especially containing double bonds which will be oxidized in a plasma process, yielding hydrophilic properties. For instance, a hydrophobic allyl-silane double bond can be oxidized in said plasma process into 3-hydroxypropyl, which is hydrophilic.

In a further example, APTES (3-aminopropyl)triethoxysilane, containing no double bonds, will be either oxidized into SiOₓ or polymerized into plasma without oxidation (as there is no double bond) and therefore stay hydrophobic after the plasma process.

According to a further embodiment, the second layer is deposited on the first layer by a (cold) (atmospheric pressure) plasma (spray) process. This may provide an excellent adhesion of the second layer on the first layer.

According to a further embodiment, the second layer comprises functional silanes/siloxanes that form a stable bond with the dielectric material and are either hydrophobic or hydrophilic, depending on the dielectric material (the surface tension of the second layer may be selected according to the surface tension of the dielectric material). The second layer may comprise silane/siloxane functional (organic) groups that react with the dielectric material, such as alcohol, amine, thiol-, epoxy- or double bonds as allyl-groups and a mixture of these groups. Further, functional silanes/siloxanes can be used, such as epoxysilane, epoxysiloxane, aminosilane, aminosiloxane, allylsilane, allylsiloxane, hexamethyldisiloxane.

According to a further embodiment, the at least one glass barrier layer comprises silicon dioxide (SiO₂), in particular at least one silane and/or siloxane compound/component. This may provide the advantage that an established and cost-efficient industry material can be directly applied and eventually functionalized as desired.

In an example, the silane/siloxane is only partially oxidized into SiOx, e.g. during a plasma process. The polymerized silanes/siloxanes may form SiOx—R, with R giving the functionality of the layer (either a hydrophilic group like amine and alcohol or a hydrophobic group like methyl).

According to a further embodiment, the at least one glass barrier layer comprises particles that are (at least partially) embedded in the at least one glass barrier layer. In this manner, specific (surface) properties may be provided.

In particular, the particles may improve the integrity, which may be crucial for high frequency applications. Furthermore, the particles may be chosen as plasma etchable to enable patterning and via plating during further production steps.

According to a further embodiment, the particles comprise at least two different shapes. Thereby, the particles may be adapted to specific applications in a flexible manner. The shapes are hereby not limited and may be for example rectangular, circular, or polygonal. Further, the shapes may include a star, a triangle, a sphere, a shape with spikes, etc.

According to a further embodiment, the partially embedded particles affect the surface roughness of the at least one glass barrier layer. Thereby, the (normally smooth) glass barrier layer surface may be adapted to a specific roughness, if desired. For example, a roughness Ra of 300 nm or smaller may thereby be implemented.

According to a further embodiment, the embedded particles comprise a metal oxide, for example SiO₂, TiO₂, Al₂O₃, fused silica, or zeolithe.

According to a further embodiment, the embedded particles are non-porous particles. According to a further embodiment, the particles can be dry-etched by fluorine plasma gases. Optionally, the particles can be coated to improve the dispersion and the adhesion with the surrounding glass barrier layer.

According to a further embodiment, the embedded particles impart hydrophilic or hydrophobic properties. Depending on the material/surface of the particles, they may provide either hydrophobic or hydrophilic properties, in particular in addition to the glass barrier main surface properties.

According to a further embodiment, the embedded particle diameters are in the micrometer range (1 μm to 1000 μm) and/or nanometer range (1 nm to 1000 nm). This enables a certain design flexibility. Preferably, the particle diameters may be in a range of a surface roughness, for example lower than 500 nm, in particular 300 nm or lower. Further, the particle diameter may be larger than 100 nm, in particular larger than 200 nm.

According to a further embodiment, there can be 10% or more, in particular 15% or more, particles with respect to the glass barrier layer material (volume or mass).

According to a further embodiment, there can be 30% or less, in particular 15% or less, particles with respect to the glass barrier layer material (volume or mass) (otherwise, it may be an amorphous layer in an example).

According to a further embodiment, the embedded particles are at least partially embedded in the first surface/portion and/or the first layer and/or in the second surface/portion and/or the second layer. This may provide the advantage that the robust adhesion between the respective layer structure and the glass barrier layer is further improved.

According to a further embodiment, the electrically insulating layer structure comprises an organic material, in particular a resin, more in particular a reinforced resin, e.g. a fiber-reinforced resin (prepreg) or a sphere-reinforced resin. Thereby, economically important materials from the component carrier industry can be directly applied.

According to a further embodiment, the electrically insulating layer structure comprises an inorganic material, in particular a glass (being different from the glass barrier layer) or a ceramic. Also, these materials may be relevant in specific applications.

According to a further embodiment, the electrically conductive layer structure comprises a metal foil, in particular a copper foil. Thereby, economically important materials from the component carrier industry can be directly applied.

According to a further embodiment, the product comprises an adhesion between the electrically conductive layer structure (and/or the electrically insulating layer structure) and (via) the at least one glass barrier layer of 40 N/m or more, in particular 100 N/m or more, in particular 400 N/m or more, more in particular 500 N/m or more. Accordingly, a very efficient and robust adhesion can be provided.

In an example, it may be seen a challenge to obtain reliable adhesion on a smooth (e.g. 100 nm roughness) metal layer. Nevertheless, the adhesion of glass barrier layer (SiOx/SiOR layer) on the (smooth) metal layer can be stronger than the bonding of the dielectric layer to the glass barrier layer.

In a specific example, the adhesion withstands a solder dip test two times during 60 seconds (usually it would be only 10 s). The adhesion after six times reflow without moisture may still be >500 N/m.

According to a further embodiment (wherein the product can be configured as a multi-layer component carrier), the product further comprises a plurality of electrically conductive layer structures, being at least partially coated by respective glass barrier layers (see e.g. FIG. 3). Thereby, the highly efficient binding between electrically conductive layer structures and electrically insulating layer structures may be ensured throughout the whole multi-layer stack of a component carrier product, resulting in a highly stable and reliable product.

According to a further embodiment, the glass barrier layer may be in direct contact with at least one surface, in particular two or more (three or more, four or more) surface(-portion)s of the electrically conductive layer structure and/or the electrically insulating layer structure.

According to a further embodiment, the product further comprises at least two glass barrier layers (in particular three or more, four or more, etc.). Preferably, the at least two glass barrier layers are (at least partially) in contact to each other (for example one formed (at least partially) above the other).

According to a further embodiment, the portions that are in contact of the at least two glass barrier layers comprise the same surface tension, preferable hydrophobic surfaces or hydrophilic surfaces. Thereby, the efficient adhesion properties may be provided throughout the whole component carrier layer stack.

According to a further embodiment, the glass barrier layer has been manufactured with a plasma (spray) process, in particular an atmospheric pressure plasma process, more in particular with a cold atmospheric pressure plasma process. The manufacturing process may be reflected in the product by the presence of not fully oxidized functional groups (whereby fully oxidized functional groups would be expected in case of a hot (atmospheric pressure) plasma process) and/or a higher carbon content in comparison to a hot (atmospheric pressure) plasma process. The differences may be detectable with established methods such as STM, AFM, FTIR, SEM, IRRAS, XPS, etc.

This may provide the advantage that the described glass barrier layer and the corresponding advantages can be formed using a reliable and cost-efficient manufacturing process. In comparison to established plasma spray processes, a cold (atmospheric pressure) plasma process may be more economic. In particular, costs of heating, vacuum, or argon gas may be saved.

According to a further embodiment, forming the glass barrier layer comprises providing a glass barrier layer preform that comprises at least one silane and/or siloxane compound, and/or performing a (atmospheric pressure) plasma process, thereby partially oxidizing the glass barrier layer preform to form silicon dioxide from at least part of the silane and/or siloxane compounds, to form the glass barrier layer. Accordingly, an oxidation may be performed directly in the (cold atmospheric pressure) plasma process, thereby omitting an additional post-oxidation process.

In an example, the (liquid) silane/siloxane oxidation may occur during (cold) plasma process, when precursors are evaporated and mixed with the plasma gas, acting as a carrier. Before the plasma process, pre-activation can be conducted to activate the surface by increasing the surface energy and burning away the dust on the substrate. This step may be particularly important for a very smooth surface and/or surface with low wetting properties.

According to a specific embodiment, the glass barrier layer is applied by an atmospheric pressure plasma spray coating process using air or nitrogen containing 1-10 % oxygen as a carrier gas. Silane/siloxane components and optionally nano-or microparticles may be fed to the atmospheric pressure plasma spray coating process by a suitable method such as a nebulizer into the air or a nitrogen carrier gas flow. Plasma activation may then be done by atmospheric pressure plasma during the deposition process, in particular on a metallic surface.

According to a further embodiment, the method further comprises providing the glass barrier layer, in particular on the electrically conductive layer structure, by a cold (atmospheric pressure) plasma process, in particular at a temperature of 200° or lower, in particular 150° or lower. The cold plasma process saves energy costs and may function surprisingly efficiently in comparison to a hot plasma process. Further, a vacuum is avoided, that requires further economic efforts.

Alternatively, a hot atmospheric pressure plasma process (in particular at a temperature of more than 200°) can be applied.

According to a further embodiment, the method further comprises cleaning the surface of the electrically conductive layer structure or the electrically insulating layer structure by the (cold atmospheric pressure) plasma process before providing the glass barrier layer. This measure may further improve the adhesion properties. In an embodiment, (oxidation and) cleaning may be performed within the plasma process.

According to a further embodiment, the method is (essentially) free of a sputtering process, in particular a physical vapor deposition (PVD) or a chemical vapor deposition (CVD) process. In particular, the method is (essentially) free of a hot (atmospheric pressure) plasma process. As discussed above, a (cold atmospheric pressure) plasma process may be more economic and less cumbersome yet providing comparable results.

According to a further embodiment, the method comprises roughening a surface of the electrically conductive layer structure and then forming the glass barrier layer on the rough surface.

According to a further embodiment, the method comprises roughening a surface of the glass barrier layer and then forming the electrically conductive layer structure on the rough surface.

According to a further embodiment, a UV-sensitive functional silanes/siloxanes, such as thiol-and allyl-siloxanes or silanes, is added to the feed stream to allow a functionalization of the layer by UV light. After patterning of the UV-sensitive glass barrier layer, selective (electroless) metal deposition can be applied.

According to a further embodiment, one plasma post-treatment step (such as plasma oxidation step or amine functionalization) is applied after each deposited glass barrier layer to thereby improve the

According to a further embodiment, the described process of forming the glass barrier layer may be applied in combination with other component carrier manufacturing processes, e.g. subtractive processes, in particular etching, or additive processes, e.g. (m)SAP and/or NIL (nanoimprint lithography) (before or after the steps listed above).

According to a further embodiment, the method is (essentially) additive and (essentially) free of (micro-) etching. As the surface thickness is in the nanometer range, the roughness of the electrically conductive layer structure remains the same. Only if embedded particles are added inside the glass barrier layer, will the overall roughness (for example copper surface around 100 nm roughness plus a glass barrier layer with around 300 nm roughness from particles) be changed. The electrically conductive layer structure surface roughness in itself may remain the same.

According to a further embodiment, for fine-line and high-frequency applications, a smooth metal (copper) surface is important. Otherwise, a potential skin effect may diminish the electrical properties. For example, for a 2 μm line/space, micro-etching of 0.5 μm may not be applicable, because otherwise one fourth of the lines could be etched away.

According to an embodiment, the adhesion between a smooth metal layer (copper foil) (e.g. surface roughness <100 nm) and a dielectric layer (e.g. prepreg) is improved. The fine lines may be structured by wet etching of the metal layer. Additionally or alternatively, the adhesion between a very smooth dielectric layer (such as glass, PID, ABF®, etc. (e.g. surface roughness <100 nm) and fine lines formed by metal plating may be improved. ABF is a registered mark of the Ajinomoto Co., Inc. of Tokyo, Japan.

According to an embodiment, fine lines are applied, e.g. <15 μm line space, especially <5 μm line/space. Usually, when it comes to fine lines, the adhesion may be very critical, so only an expensive sputtering process can give sufficient adhesion to fine lines formed by plating. Other existing processes for sufficient adhesion between metal and dielectric require a wet etching of the metal structure or dielectric substrate, thereby generating a roughness of a minimum of 150 nm.

According to an embodiment, another function of the glass barrier layer is to avoid copper migration, which may be critical for fine-line spacing.

According to an embodiment, at least a portion of the electrically conductive layer structure is in contact with both of the two main surfaces of the glass barrier layer. This can be the case, for example, when the electrically conductive layer structure is oriented vertically or tilted in the stack. In a further embodiment, the electrically conductive layer structure may thereby contact the two main surfaces of two or more glass barrier layers.

According to an embodiment, the glass barrier layer comprises self-aligning properties. This may have the advantage of better adhesion between at least two layers of the product.

In this document, the term “self-aligning property” may define alignment of the glass barrier layer so, that the hydrophilic surface of the glass barrier layer may be oriented towards another hydrophilic surface, in particular in direct contact with another hydrophilic surface, and/or that the hydrophobic surface of the glass barrier layer may be oriented toward another hydrophobic surface, in particular in direct contact with another hydrophobic surface. Hydrophilic surfaces may comprise electrically conductive layer structures and/or hydrophilic portions of the glass barrier layer. Hydrophobic surfaces may comprise electrically insulating layer structures and/or hydrophobic portions of the glass barrier layer.

According to a further embodiment, the product further comprises: at least one (at least partially (metal-) filled) via, and a titanium-containing seed layer (for example a Ti/Cu seed layer), wherein the titanium-containing seed layer is located only at the sidewall and/or the bottom of the at least one via. In other words, the product may be, in an example, (essentially) free of the titanium-containing seed layer (in particular regarding the glass barrier layer) except at sidewall/bottom of at least one via, in particular a fine pattern via.

According to a further embodiment, the product further comprises at least one (at least partially (metal-) filled) via, and a titanium-containing seed layer (for example a Ti/Cu seed layer), wherein the titanium-containing seed layer is located only at the sidewall and/or the bottom of the at least one via. In other words, the product may be, in an example, (essentially) free of the titanium-containing seed layer (in particular regarding the glass barrier layer) except at a sidewall/bottom of at least one via, in particular a fine pattern via.

According to a further embodiment, the glass barrier layer improves the adhesion between a very smooth (Ra<100 nm roughness) electrically insulating layer structure (dielectric) such as glass, PID, ABF®, and fine line electrically conductive traces/pattern (e.g. formed by copper plating). In an example, a seed layer for an additive process can be E-less or sputtered. In the case of Ti/Cu sputtering, the Ti layer could be (at least partially) replaced by the glass barrier layer. Thereby, costs and efforts may be saved, while the (electrical) performance is increased (see also FIG. 5).

Usually, to form fine lines (e.g. <5 μm) and small vias, a sputtered Ti/Cu seed layer can be used. Titanium can hereby act as a barrier and as an adhesion promoter while ensuring the electrical connection. However, the titanium-containing (seed) layer may be expensive, require special chemistry to be etched, and is less conductive than copper (e.g. twenty times less).

These drawbacks may be overcome using the described glass barrier layer. For example, a silane adhesion and barrier layer, coated with cold plasma (glass barrier layer), is replacing the Ti layer, providing the advantage that no Ti etching is required and that there may be no loss of the electrical conductivity.

According to a further embodiment, the method is (essentially) free of a titanium-etching step.

Generally, an additive production step (e.g. (m)SAP, NIL process) can be applied to an electrically conductive layer. Then a protection mask can be applied and developed to create portions, where the electrically conductive layer (metal) is exposed. Then a plating step can be performed. Afterwards, the protection layer and the base material of the electrically conductive layer (metal) may be removed in order to not electrically connect/conduct the entire layer. When sputtering is applied to create an electrically conductive seed layer to start an additive process step, a thin titanium layer can be created on top of an insulating layer structure. On top of the titanium layer, a copper layer may then be provided.

Since titanium can be removed together with the protection layer according to an embodiment (see e.g. FIG. 5E), only titanium is then available in the vias. In other words, the titanium etching step may be skipped (and cost/efforts may be saved), since titanium is only part of the electrically conductive via.

In an embodiment, the component carrier is configured as one of a printed circuit board, a substrate (in particular an IC substrate), and an interposer.

In an embodiment, the component carrier is shaped as a plate. This contributes to the compact design, wherein the component carrier nevertheless provides a large basis for mounting components thereon. Furthermore, in particular a naked die as an example of an embedded electronic component, can be conveniently embedded, thanks to its small thickness, into a thin plate such as a printed circuit board.

In an embodiment, the component carrier stack comprises at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact.

In the context of the present application, the term “stack” may particularly denote a sequence of two or more layer structures formed on top of each other. For instance, layer structures of a layer stack may be connected by lamination, i.e. the application of heat and/or pressure. Preferably, the stacked layer structures may be arranged parallel to each other.

In the context of the present application, the term “layer structure” may particularly denote a continuous layer, a patterned layer, or a plurality of non-consecutive islands within a common plane.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in the case of a Chip Scale Package (CSP)). In another embodiment, the substrate may be substantially larger than the assigned component (for instance in a flip chip ball grid array, FCBGA, configuration). More specifically, a substrate can be understood as a carrier for electrical connections or electrical networks as well as a component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo-and/or thermosensitive molecules) like polyimide or polybenzoxazole.

In an embodiment, the at least one electrically insulating layer structure (dielectric layer) comprises at least one of the group consisting of a resin or a polymer, such as epoxy resin, cyanate ester resin, benzocyclobutene resin, bismaleimide-triazine resin, polyphenylene derivate (e.g. based on polyphenylenether, PPE), polyimide (PI), polyamide (PA), liquid crystal polymer (LCP), polytetrafluoroethylene (PTFE) and/or a combination thereof. Reinforcing structures such as webs, fibers, spheres or other kinds of filler particles, for example made of glass (multilayer glass) in order to form a composite, could be used as well. A semi-cured resin in combination with a reinforcing agent, e.g. fibers impregnated with the above-mentioned resins is called prepreg. These prepregs are often named after their properties e.g. FR4 or FR5, which describe their flame-retardant properties. Although prepreg particularly FR4 are usually preferred for rigid PCBs, other materials, in particular epoxy-based build-up materials (such as build-up films) or photoimageable dielectric materials, may be used as well. For high-frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure (for example electric interconnection, terminal, pad, via, etc.) comprises at least one of the group consisting of copper, aluminum, nickel, silver, gold, palladium, tungsten, magnesium, carbon, (in particular doped) silicon, titanium, and platinum. Although copper is usually preferred, other materials or coated versions thereof are possible as well, in particular materials coated with supra-conductive material or conductive polymers, such as graphene or poly(3,4-ethylenedioxythiophene) (PEDOT), respectively.

At least one further component may be embedded in and/or surface mounted on the stack.

The component and/or the at least one further component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be either embedded or surface mounted for the purpose of facilitating heat dissipation. Suitable materials are defined according to their thermal conductivity, which should be at least 2 W/mK (milliKelvin). Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SIC), gallium arsenide (GaAs), gallium nitride (GaN), gallium oxide (Ga₂O₃), indium gallium arsenide (InGaAs), indium phosphide (InP) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be a IC substrate, an interposer or a further component carrier, for example in a board-in-board configuration. The component may be surface mounted on the component carrier and/or may be embedded in an interior thereof. Moreover, other components, in particular those which generate and emit electromagnetic radiation and/or are sensitive with regard to electromagnetic radiation propagating from an environment, may be used as a component(s).

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), Electroless Nickel Electroless Palladium Immersion Gold (ENEPIG), gold (in particular hard gold), chemical tin (chemical and electroplated), nickel-gold, nickel-palladium, etc. Also nickel-free materials for a surface finish may be used, in particular for high-speed applications. Examples are ISIG (Immersion Silver Immersion Gold), and EPAG (Electroless Palladium Autocatalytic Gold).

In a further example, for high frequency (HF) and radar application products, smooth metal/copper structures, such as antennas and air-filled waveguides, are preferably protected with a special low-loss surface finish. An HF efficient surface finish is for example EPIG or ENEPIG. However, these materials are expensive, so that often immersion tin is used instead as a surface finish, even though the HF performance of immersion tin is generally lower.

Thus, there may be a need to provide an efficient and robust coating, in particular for a HF/radar application. Specifically, there may be a need to provide (in particular for existing HF products as well as for future air-filled waveguide products) a thin, dielectric, economic coating with good HF performance, and excellent adhesion on smooth metal/copper.

According to an embodiment, the product is configured for a HF and/or radar application, in particular as a waveguide. This may bring the advantage of providing a higher and/or more sophisticated function to the product, since the at least one glass barrier layer is not prone to generate signal losses, in particular in the HF field.

According to an embodiment, the glass barrier layer is configured for a HF and/or radar application, e.g. for coating electrically conductive structures such as antenna traces. This may bring the advantage of protecting exposed constituents required for HF and/or radar applications, for example an antenna structure, from environmental influences, for example oxidation from oxygen.

According to an embodiment, there is described a use of the described glass barrier layer for coating antenna structures, in particular regarding HF and/or radar applications. This may bring the advantage of ensuring high quality transmission and/or receiving performance having low signal losses. Additionally, the glass barrier layer may act as a mechanical and/or chemical protection layer the antenna structure, since the glass barrier layer is hermetically sealing the antenna structure.

According to an embodiment, the product/glass barrier layer is applied in at least one of a HF application, a radar application, a communication application, in particular one of 3G to 6G, an IC substrate, a fine-line application. This may bring enhanced physical and/or mechanical performance and/or properties due to the chemical properties of the glass barrier layer while hardly increasing the total thickness of the product. Therefore, the additional (and superior) physical and/or chemical and/or mechanical properties compensate the additional thickness, which is smaller than 5 μm.

According to an embodiment, the glass barrier layer is selectively applied (to specific antenna areas) using a photolithography process. According to an embodiment, at least one of the following steps may be performed: i) photo process to selectively expose the metal (copper) areas, in particular antenna areas) to be coated; ii) plasma coating of said open metal areas with the glass barrier layer; iii) photo resist (e.g. ethanolamine) stripping.

Thus, established processes (such as photolithography) may be directly applied to coat only specific areas with the glass barrier layer.

According to an embodiment, the glass barrier layer (even with a thickness in the nanometer range) may be detectable, for example on electrically conductive layer structure, i.e. metal traces (antenna structures) and/or electrically insulating layer structures, e.g. using FTIR analysis, or focus ion beam (FIB) analysis. Even if the applied glass barrier layer is smaller than 1 μm, it may be detectable using proper measuring techniques.

According to an embodiment, two or more surface finish materials may be used for the product, one of them being the glass barrier layer. For example, besides said glass barrier layer, other surface finishes as listed above may be used (e.g. immersion tin, ENIG). Further, a solder mask (solder resist) can be applied with or without the glass barrier layer between the metal structure and the solder mask material. Thereby, a high design flexibility is provided, so that a plurality of applications can be efficiently realized (compare FIGS. 8 and 9).

According to an embodiment, the product comprises a cavity at least partially covered/coated by the glass barrier layer. For example, the bottom and/or the sidewalls of the cavity are covered by the glass barrier layer. In particular, a metal layer/structure in the cavity may be covered/coated by the glass barrier layer (compare e.g. FIGS. 10 and 11). This may enable a highly reliable protection without reducing HF/radar application performance.

According to an embodiment, a glass barrier layer (surface finish) may be comparable or even more cost-efficient than immersion tin.

In a further example, there may be a need to provide an adhesion promoter (in particular in a non-etching manner) in an efficient manner.

For example, regarding fine-line applications (e.g. lower than 10 μm line/space), the thickness of fine-line metal traces is generally below 5 μm. Conventional micro-etch processes may etch 0.2 μm metal before applying a silane adhesion promoter. However, these products may suffer from reduced adhesion, for example after 500 cycles in HAST (highly accelerated stress test).

According to an embodiment, the glass barrier layer is used as an alternative (highly efficient and reliable) surface finish and/or adhesion promoter. This may bring the advantage of reducing warpage, since the same material is used, having identical CTE values/properties at various layers in the stack of the product, compared to the usually applied surface finishes, for example tin or solder resist. Furthermore, the glass barrier layer may be used for a multi-functional purpose, as said adhesion promotion and surface finish, which enables the production of a big variety of different product (features) using one process step.

According to an embodiment, at least part of the glass barrier layer is formed by a surface treatment process, e.g. a plasma (coating) process and/or a chemical binding reaction (in particular with an adhesion promoting agent, more in particular a silane coupling agent). This may bring the advantage of changing the adhesion and/or surface properties to a required value, due to the fact that two different, preferably consecutive, process steps are performed.

According to an embodiment, at least a part (in particular the first layer) of the glass barrier layer is formed by a plasma (coating) process, e.g. PVD or CVD. Thus, an established process to form an (ultra) thin layer can be directly applied. In an embodiment, a plasma (coating) process may be performed in a cost-efficient manner, in particular with very low chemical consumption.

According to an embodiment, the plasma-coating layer comprises a thickness of 300 nm or less, in particular 100 nm or less. This may bring the advantage of amending surface properties of the final or intermediate product without substantially interfering with the overall thickness of the stack. Therefore, the added plasma-coating layer may contribute to 1% or less, in particular 1%, in particular 10 ppm, of the overall thickness of the stack.

According to an embodiment, at least a part (in particular (at least part of) the second layer) of the glass barrier layer is formed by a chemical binding reaction with a (silane) coupling agent. This may provide the advantage that a strong adhesion to dielectric material (resin) can be provided in a straightforward manner.

According to an embodiment, the chemical binding reaction comprises a silane coating, specifically a liquid silane coating process.

According to an embodiment, the chemical binding reaction is performed after the plasma (coating) process. This may provide the advantage that two established methods can be combined in a completely new manner, thereby providing excellent adhesion properties between metal and resin materials.

According to an embodiment, the chemical reaction comprises forming silanol groups at the silane coupling agent, in particular by hydrolysis. Silanol groups may efficiently react chemically (forming covalent bonds) with hydroxy groups at the surface of the (first layer of the) glass barrier layer.

According to an embodiment, the chemical reaction comprises coupling (in particular via the silane coupling agent) long carbon chains to the glass barrier layer (surface). The long carbon chains (molecules) may function as anchors in the resin material, thereby highly improving adhesion (compare FIG. 6). In the present context, the term “long carbon chain” may in particular refer to molecules with at least six carbon atoms (in a row), in particular at least eight carbon atoms. Alternatively, the term “long carbon chain” may in particular refer to molecules with at least atoms (in a row) comprising carbon atoms and/or nitrogen atoms and/or oxygen atom and/or sulfur atoms and/or silicon atoms.

In a specific example, hydroxy (OH) groups at the surface of the glass barrier layer may chemically react with silanol (Si—OH) groups and/or alkoxy (Si—OR) of the silane coupling agent, thereby providing the following molecular structure: [surface glass barrier layer]-O—Si (OH)₂—(CH₂)₆—CH₃.

In an embodiment, the long carbon chain adhesion promoter (e.g. second layer of glass barrier layer) may provide excellent bonding to (the rest of) the glass barrier layer and the dielectric material (resin/prepreg). In an embodiment, the plasma (nano-) layer (e.g. first layer of glass barrier layer) may provide excellent adhesion on a smooth (e.g. less than 100 nm) metal (copper) surface. Said plasma layer may provide hydroxy binding groups for efficiently coupling the long carbon chain silane adhesion promoter.

In an embodiment, the nano/plasma (first layer of the) glass barrier layer may imitate/copy the mechanical properties of the metal layer underneath, thereby providing good adhesion to said metal layer.

According to a specific embodiment, a special plasma silane coating process is described, which allows manufacturing of a unique material combination, e.g. a nanometer smooth copper coated with SiOx nano-glass (barrier) layer with excellent adhesion. At least one of the following aspects may be covered by the described process: i) the glass barrier layer (nano-layer) directly deposited on copper structures should be “HF transparent”; ii) the nano-layer thickness may copy the mechanical properties of smooth HF antenna, i.e. no delamination; iii) economic low cost plasma spray coating process may have four functions in one process step: a) it activates metal prior deposition to nano-coating to avoid delamination, b) it deposits uniformly in nanometer thickness range plasma activated silanes by nebulizer technology, c) in situ hardening and polymerizing of very reactive plasma activated silane molecules, d) 3D structures such as sidewalls or holes can be coated (without having a vacancy and/or cavity).

### BRIEF DESCRIPTION OF THE DRAWINGS

The embodiments defined above and further embodiments consist with the disclosure are apparent from the examples of embodiment to be described hereinafter and are explained with reference to these examples of embodiment.

FIG. 1A and FIG. 1B illustrate a product according to an example embodiment of the present disclosure.

FIG. 2A, FIG. 2B, FIG. 2C, FIG. 2D, FIG. 2E, FIG. 2F, FIG. 2G, FIG. 2H, FIG. 2I, FIG. 2, FIG. 2K, and FIG. 2M illustrate a method of manufacturing the product according to an example embodiment of the present disclosure.

FIG. 3 and FIG. 4 respectively illustrate a multi-layer component carrier according to example embodiments of the present disclosure.

FIG. 5A, FIG. 5B, FIG. 5C, FIG. 5D, FIG. 5E, FIG. 5F, FIG. 5G, FIG. 5H, FIG. 5I, FIG. 5J, and FIG. 5K illustrate a method of manufacturing the product with fine line vias according to an example embodiment of the present disclosure.

FIG. 6 shows schematically the glass barrier layer as an adhesion promoter according to an example embodiment of the present disclosure.

FIG. 7 shows a method of coupling long carbon chain molecules to the glass barrier layer according to an example embodiment of the present disclosure.

FIG. 8, FIG. 9, FIG. 10, and FIG. 11 respectively illustrate products for antenna applications with the glass barrier layer according to example embodiments of the present disclosure.

### DETAILED DESCRIPTION OF THE ILLUSTRATED EMBODIMENTS

The illustrations in the drawings are schematically presented. In different drawings, similar or identical elements are provided with the same reference signs.

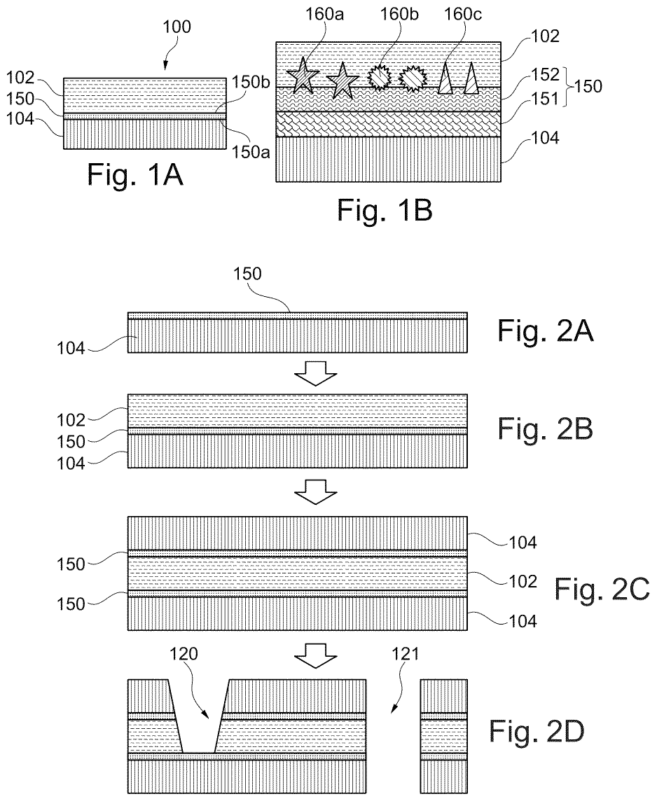

FIG. 1A illustrates a (component carrier) product 100 according to an example embodiment of the present disclosure. In this basic example, the product 100 comprises three layers: i) an electrically insulating layer structure 102, e.g. a prepreg, ii) an electrically conductive layer structure 104, e.g. a copper foil, and iii) at least one glass barrier layer 150 sandwiched between the electrically insulating layer structure 102 and the electrically conductive layer structure 104.

The at least one glass barrier layer 150 comprises two main surfaces 150a, 150b, wherein the first main surface 150a is in direct contact with the electrically conductive layer structure 104 and the second main surface 150b is in direct contact with the electrically insulating layer structure 102. The first main surface 150a is located on an opposed side to the second main surface 150b. To establish an efficient and robust adhesion, the two main surfaces 150a, 150b comprise a different adhesion property (here a different surface tension), being optimized to the respective layer structure 102, 104 in direct contact.

The glass barrier layer is thereby additionally configured to suppress migration of chemical species (e.g. oxygen or vapor) between the electrically insulating layer structure 102 and the electrically conductive layer structure 104.

The at least one glass barrier layer 150 is configured extremely thin here with a thickness (in stack thickness direction) in the lower range nanometer range (50 nm to 350 nm). Due to the strong adhesion between glass barrier layer 150 and the electrically conductive layer structure 104, the latter can be realized as smooth surface (with a surface roughness Ra of 100 nm or smaller) copper foil. The glass barrier layer 150 comprises silicon dioxide and at least one silane and/or siloxane compound.

FIG. 1B illustrates a more detailed embodiment of the (component carrier) product 100 according to an exemplary embodiment of the present disclosure, wherein the glass barrier layer 150 comprises a first layer 151, which includes the first main surface 150a, and a second layer 152, which includes the second main surface 150b. While the first layer 151 comprises hydrophilic properties (e.g. realized by hydrophilic functional groups), in particular at first main surface (region) 150a, the second layer 152 comprises hydrophobic properties (e.g. realized by hydrophobic functional groups), in particular at second main surface (region) 150b. The first main surface 150a and the second main surface 150b are located on opposed sides. In other words, the first main surface 150a and the second main surface 150b are not in direct physical contact with each other.

Furthermore, particles 160 (e.g. metal oxides) are partially embedded in the at least one glass barrier layer 150, in particular in this example in the second layer 152. Said particles 160 comprise different shapes, in this example: star shape 160a, spherical shape 160b, and triangular shape 160c. The partially embedded particles 160 affect the surface roughness of the glass barrier layer 150 and are further partially embedded in the electrically insulating layer structure 102.

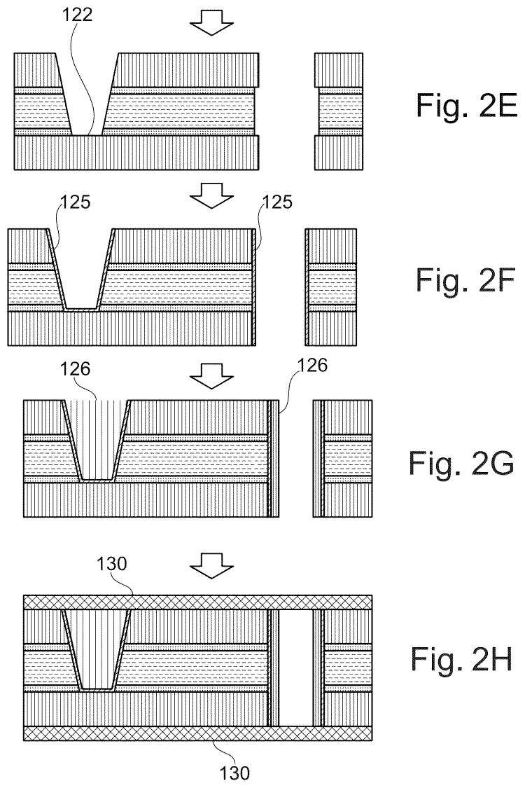

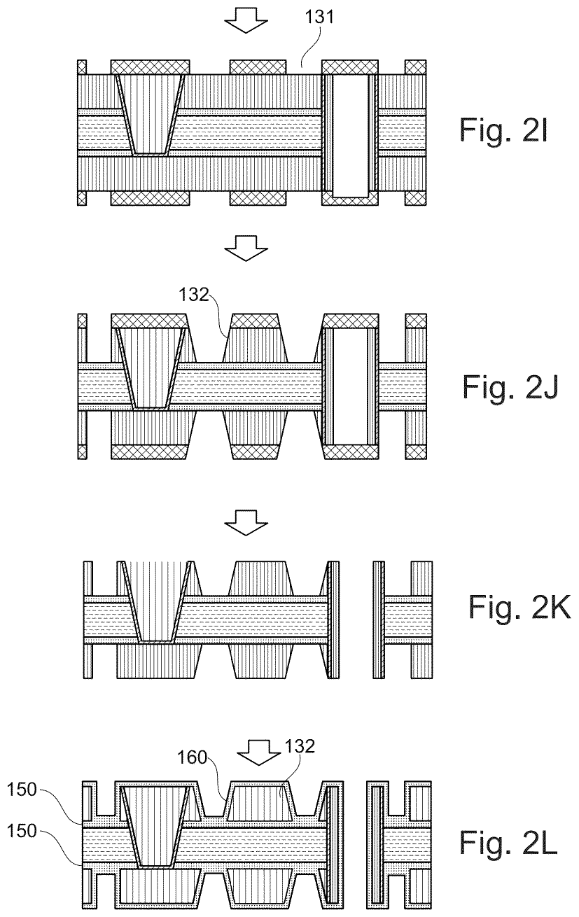

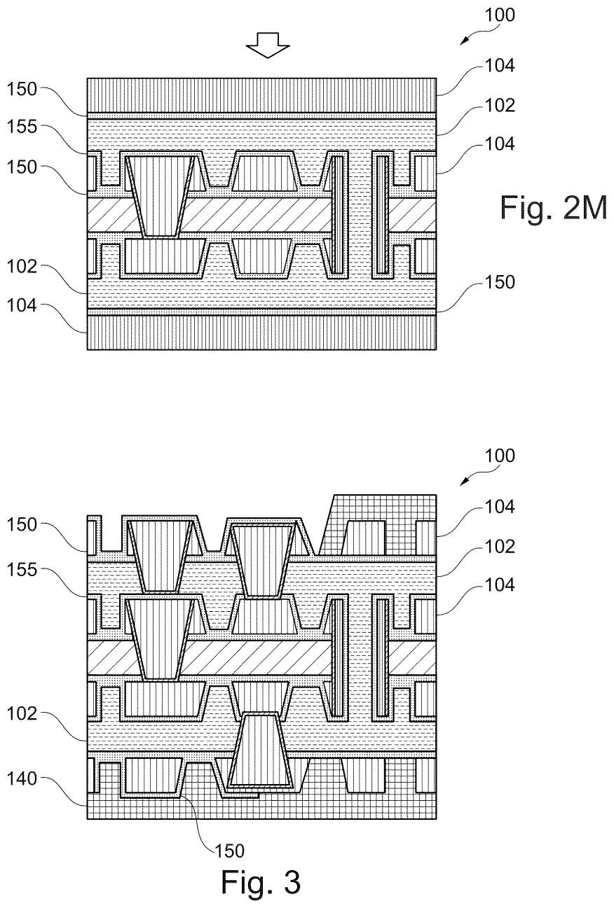

FIG. 2A, FIG. 2B, FIG. 2C, FIG. 2D, FIG. 2E, FIG. 2F, FIG. 2G, FIG. 2H, FIG. 2I, FIG. 2J, FIG. 2K, FIG. 2L, and FIG. 2M illustrate a method of manufacturing the product 100 according to an example embodiment of the present disclosure.

In FIG. 2A an electrically conductive layer structure 104, e.g. a copper foil, is coated, preferably by a cold atmospheric pressure plasma process, to form a glass barrier layer 150 with different surface tension at the main surfaces.

In FIG. 2B an electrically insulating layer structure 102, e.g. a prepreg, is deposited on top of the glass barrier layer 150.

In FIG. 2C a further electrically conductive layer structure 104 and a further glass barrier layer 150 are formed in order on top of the electrically insulating layer structure 102.

In FIG. 2D a blind hole 120 and a through hole 121 are formed, e.g. by laser drilling or mechanical drilling, in the layer stack.

In FIG. 2E after the drilling process, a dry or wet etching process (e.g. containing fluoride gases) is (optionally) performed to remove the glass barrier layer 150 at the bottom 122 of the blind hole 120. As an alternative, a UV-laser cleaning process can be applied.

In FIG. 2F a (copper) seed layer 125 is applied to cover the sidewalls of the holes 120, 121 and the bottom 122 of the blind hole 120, e.g. by a sputtering process.

In FIG. 2G the blind hole 120 is completely filled by electrically conductive material (copper), in particular by plating, while only the sidewalls of the through hole 121 are covered by said material (in particular thereby forming a plated through hole).

In FIG. 2H for structuring of the electrically conductive layer structures 104 via a photolithography process, a UV-sensitive photo film 130 is deposited at the exposed surface, in particular on the electrically conductive layer structures 104. Thereby, the through hole 121 is temporarily closed.

In FIG. 2I and FIG. 2J after structuring and developing of the photo film 130, the openings form a pattern 131 in the photo film 130, which allows an etching process of the electrically conductive layer structures 104, resulting in copper (frustoconical shaped) traces 132. It can be seen that the glass barrier layer 150 is not etched during said structuring process.

In FIG. 2K after structuring of the electrically conductive layer structures 104, the photo film 130 is stripped.

In FIG. 2L on top of the electrically conductive traces 132, as well as on the glass barrier layer 150, a further glass barrier layer 155 is deposited, preferably by a cold atmospheric pressure plasma process. In this example, all exposed surfaces are covered by said further glass barrier layer 155. The further glass barrier layer 155 extends over a broader stack thickness portion (two adjacent, or more layers and distance between the two adjacent layers), thereby covering surfaces parallel to the main elongation direction of the layer stack (along x-direction) and sidewalls of the (tapered shaped) traces 132. This is in contrast to the glass barrier layer 150, which is extending within a plane.

In FIG. 2M the further glass barrier layer 155 is covered by a further electrically insulating layer structure 102. Then, another glass barrier layer 150 is deposited and, on top, another electrically conductive layer structure 104 is formed.

FIG. 3 illustrates a product in the form of a multi-layer component carrier 100 according to an example embodiment of the present disclosure. The component carrier 100 is obtained based on the component carrier 100 of FIG. 2M. The glass barrier layer 150 is shown here as a surface finish for outer electrically conductive layer structures 104, e.g. for HF antenna structures. Therefore, the glass barrier layer 150 can be applied in areas where soldering of components is not required, e.g. as a copper corrosion protection.

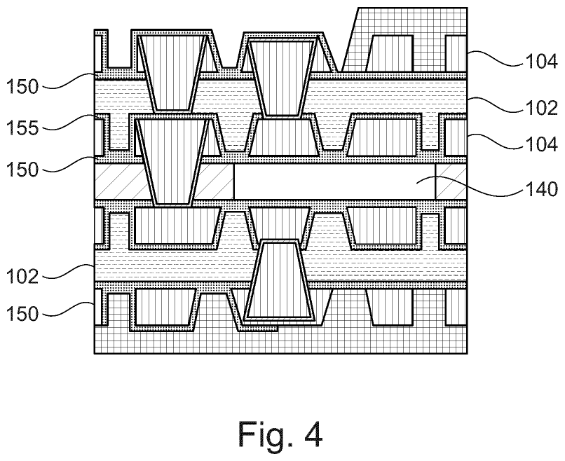

FIG. 4 illustrates a product in the form of a multi-layer component carrier 100 according to an example embodiment of the present disclosure. The product 100 of FIG. 4 is very similar to the one shown in FIG. 3, the difference being that a cavity 140 is formed in the central electrically insulating layer structure 102 (this can be a core structure, e.g. cured FR4). In this example, an electronic component can be arranged in the cavity 140, thereby being embedded in the multi-layer component carrier 100.

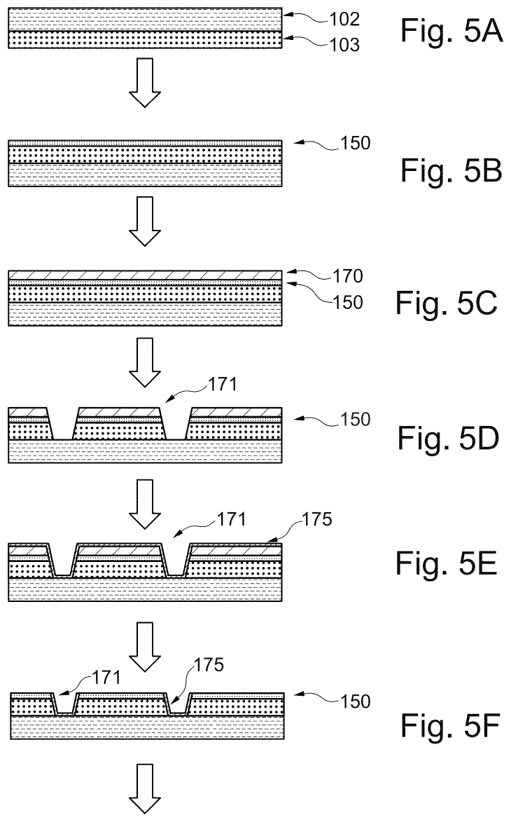

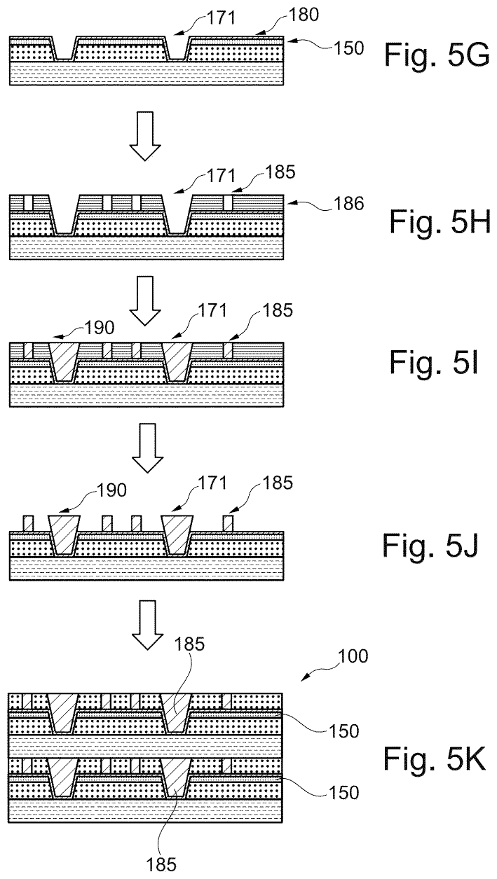

FIG. 5A, FIG. 5B, FIG. 5C, FIG. 5D, FIG. 5E, FIG. 5F, FIG. 5G, FIG. 5H, FIG. 5I, FIG. 5J, and FIG. 5K illustrate a method of manufacturing the product 100 with fine line vias according to an example embodiment of the disclosure. Specifically, Ti/Cu sputtering is used only in the vias, while a Cu layer (no Ti) is sputtered on top of the dielectric material to form an electrically conductive fine line. At the end, the Ti will remain in the vias and no Ti etching step is required for the formation of the fine line.

In FIG. 5A an electrically insulating layer structure 102 is laminated onto a core layer structure 103 (e.g. cured resin such as FR4).

In FIG. 5B the glass barrier layer 150 is formed on the electrically insulating layer structure 102 by plasma coating (cold atmospheric pressure plasma).

In FIG. 5C a protection layer 170 (e.g. a protective foil) is laminated on top of the glass barrier layer 150.

In FIG. 5D blind holes 171 are formed through the protection layer 170, the glass barrier layer 150, and the electrically insulating layer structure 102, e.g. by laser drilling.

In FIG. 5E a (electrically conductive) seed layer 175 is formed on top of the protection layer 170 and on the sidewalls and the bottoms of the blind holes 171. The seed layer 175 is provided by Ti/Cu sputtering.

In FIG. 5F the protection layer 170 and part of the Ti/Cu seed layer 175 have been removed, so that the Ti/Cu seed layer 175 only blind holes 171.

In FIG. 5G a further (electrically conductive) seed layer 175, being a Cu seed layer, is formed on the glass barrier layer 150 and the sidewalls, and the bottoms of the blind holes 171.

In FIG. 5H holes for electrically conductive (metal) traces 185 are formed on the Cu seed layer 175 using a photo resist layer 186 (resist lamination, exposure, development).

In FIG. 5I the blind holes 171 are filled by metal (copper) using plating. Further, using the same plating process, the holes 185 are also filled by the metal to obtain fine pattern metal traces.

In FIG. 5J the photo resist 186 is stripped, leaving the metal traces 185 exposed. A further step of copper etching (not titanium etching) can be performed.

In FIG. 5K the final product 100 is obtained with a plurality of glass barrier layers 150 and fine pattern metal traces 185. Titanium is only present at the via bottoms and sidewalls, but not around the glass barrier layer 150.

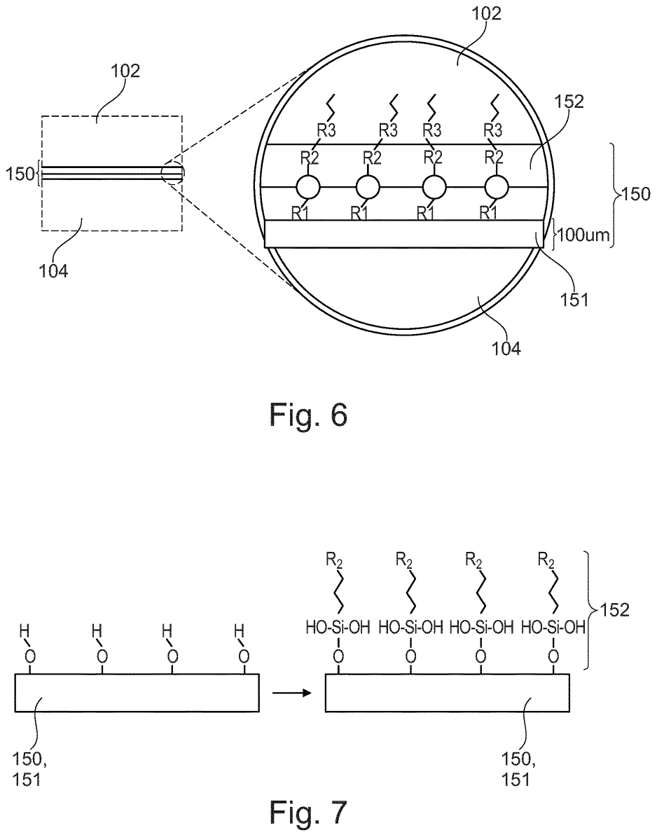

FIG. 6 shows schematically the glass barrier layer 150 as an adhesion promoter according to an example embodiment of the present disclosure. Like in FIG. 1A, the product 100 comprises three layers: an electrically insulating layer structure 102, an electrically conductive layer structure 104, and the glass barrier layer 150 sandwiched between the electrically insulating layer structure 102 and the electrically conductive layer structure 104. It is shown in detail that the glass barrier layer 150 comprises a thin first layer 151 (for example 100 nm) directly on the electrically conductive layer structure 104. Alternatively, the first layer 151 of the glass barrier layer 150 may have a thickness perpendicular to the main directions in the range between 10 nm to 700 nm, preferably smaller than 500 nm. The first layer 151 can be provided for example by a plasma process, e.g. plasma coating, and comprises preferably a hydrophilic surface (e.g. OH-groups, in particular Si—OH— and/or Si—(OH)₂— and/or Si—OH)₃— groups).

On top of the first layer 151, a second layer 152 of the glass barrier layer 150 is formed, for example using a silane coupling/coating process (see FIG. 7 below). Silane coupling agents (e.g. with silanol groups) can be attached to the surface of the glass barrier layer 150 (e.g. to hydroxy groups). As illustrated schematically, the silane coupling agent can comprise long carbon chains (six carbon atoms or more) that can function like anchors in the resin layer 102, thereby providing strong adhesion. In an example, the second layer 152 of the glass barrier layer 150 may have a thickness perpendicular to the main directions in the range between 10 nm to 500 nm. Alternatively, the second layer 152 of the glass barrier layer 150 may have a thickness perpendicular to the main directions in the range between 500 nm and 1 μm. Preferably, the second layer 152 of the glass barrier layer 150 may be larger than the first layer 151 of the glass barrier layer 150 (perpendicular to the main directions). Alternatively, the second layer 152 of the glass barrier layer 150 may be smaller than the first layer 151 of the glass barrier layer 150 (perpendicular to the main directions).

FIG. 7 shows a method of coupling long carbon chain silane coupling agents to the glass barrier layer 150 according to an example embodiment of the present disclosure. In the first place, there is provided the glass barrier layer 150 which comprises hydroxy groups at the main surface. Hereby, a first layer 151 or a second layer 152 of the glass barrier layer 150 can comprise said hydroxy groups. The hydroxy groups can also be provided in a first process step, e.g. using an oxidation reaction. Thereby, the oxidation reaction may convert at least a portion, preferably at least 50%, of the exposed surface (area) of the glass barrier layer 150 and/or the first layer 151 of the glass barrier layer 150 from elementary Silicon into Si—OH—and/or Si—(OH)₂— and/or Si—(OH)₃— groups. The oxidation reaction can be performed using a plasma process, for example comprising the use of oxygen gas and/or ozone gas, and/or a wet chemical process, for example comprising the use of hydrogen peroxide.

In a second process step, the hydroxy groups form covalent bonds with silanol (Si—OH) groups and/or alkoxy (Si—OR) groups of a silane coupling agent. In an example, the alkoxy groups may comprise methoxy and/or ethoxy groups. Alternatively, the alkoxy groups may comprise propoxy and/or tert-butoxy and/or isopropenoxy groups. The silanol groups can be formed for example by a hydrolysis of silane groups. As can be seen, the silane coupling agent comprises long carbon chains for anchoring to a resin layer.

In an example, the silane coupling agent may be at least one of the following: 3-acrylamidopropyltrimethoxysilane, acryloxymethyltrimethoxysilane, (acryloxymethyl)phenethyltrimethoxysilane, (3-acryloxypropyl)trimethoxysilane, O-(methacryloxyethyl)-N-(triethoxysilylpropyl)carbamate, methacryloxypropyltriethoxysilane, methacryloxypropylmethyldimethoxysilane, methacryloxypropyldimethylmethoxysilane, 4-aminobutyltriethoxysilane, N-(2-aminoethyl)-3-aminopropyltriethoxysilane, 3-(m-aminophenoxy) propyltrimethoxysilane, N-(3-trimethoxysilylpropyl)pyrrole, 4-amino-3,3-dimethylbutylmethyldimethoxysilane, N-(6-aminohexyl)aminomethyltriethoxysilane, N-3-[(amino(polypropylenoxy)]aminopropyltrimethoxysilane, N-butylaminopropyltrimethoxysilane, 3-(N,N-dimethylaminopropyl)aminopropylmethyldimethoxysilane, bis(3-triethoxysilylpropyl)amine, N,N′-bis[(3-trimethoxysilyl)propyl]ethylenediamine, N-allyl-aza-2,2-dimethoxysilacyclopentane, N-N-butyl-aza-2,2-dimethoxysilacyclopentane, (N,N-dimethylaminopropyl)-aza-2-methyl-2-methoxysilacyclopentane, 2-(3,4-epoxycyclohexyl)ethyltriethoxysilane, 2-(3,4-epoxycyclohexyl)ethyltrimethoxysilane, 5,6-epoxyhexyltriethoxysilane, (3-glycidoxypropyl)trimethoxysilane, (3-glycidoxypropyl)trimethoxysilane, 2-(3,4-epoxycyclohexyl)ethylmethyldiethoxysilane, hydroxymethyltriethoxysilane, N-(3-triethoxysilylpropyl)-4-hydroxybutyramide, 2-(3-trimethoxysilylpropylthio)thiophene, 2,2-dimethoxy-1-thia-2-silacyclopentane, 11-mercaptoundecyltrimethoxysilane, 5-hexenyltrimethoxysilane, 7-octenyltrimethoxysilane, vinyltris(2-methoxyethoxy)silane, N-allyl-aza-2,2-dimethoxysilacyclopentane, 1,6-bis(trimethoxysilyl)hexane.

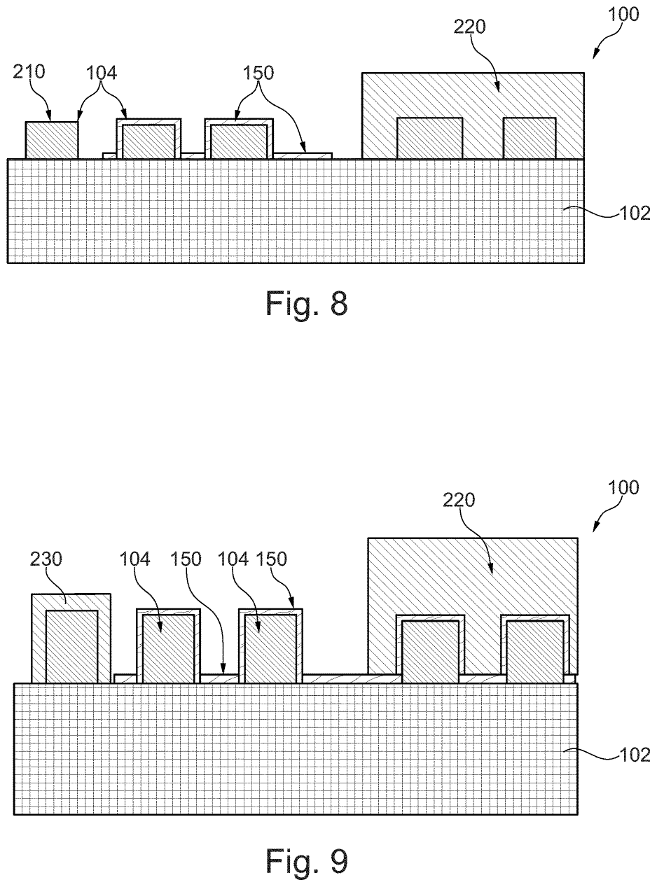

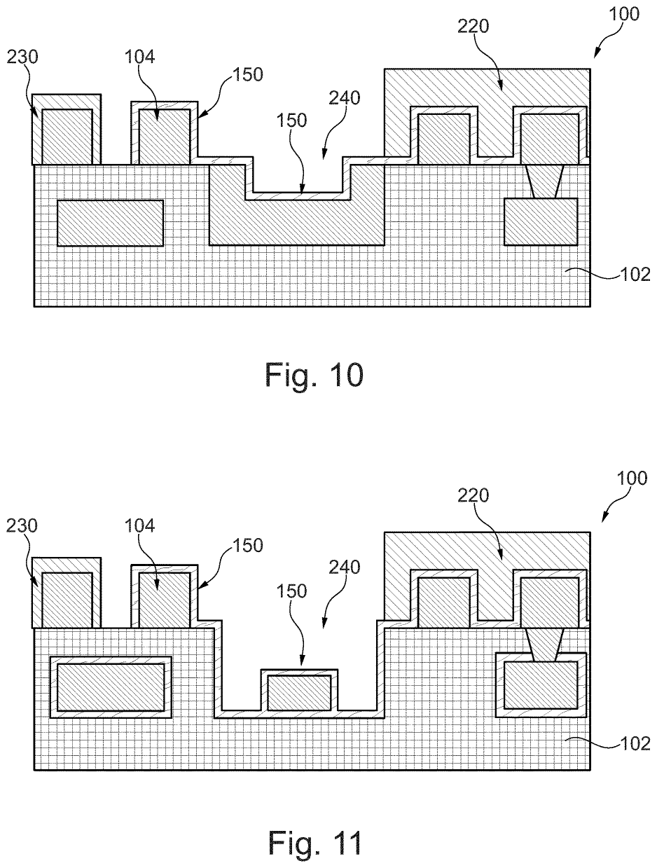

FIG. 8, FIG. 9, FIG. 10, and FIG. 11 respectively illustrate products 100 for antenna applications with the glass barrier layer 150 according to example embodiments of the present disclosure.

FIG. 8 shows an antenna structure on an electrically insulating layer structure 102 (here prepreg). The antenna structure is realized by an electrically conductive layer structure 104, here copper traces. It can be seen that two traces 104 are covered by the glass barrier layer 150 (nano-coating). In an example, the antenna structure may be entirely covered on its exposed surface including the top part and the sidewalls by the glass barrier layer. Thereby the glass barrier layer is free from cavities and/or vacancies. Alternatively, only a part of the antenna structure may be covered on its exposed surface including the top part and/or the sidewalls by the glass barrier layer. In this case, the glass barrier layer 150 is configured as a protection layer. A pad for soldering 210, preferably also constituent of the electrically conductive layer structure 104, is not covered by the glass barrier layer 150. Alternatively, the pad for soldering 210 may be partially covered by the glass barrier layer 150, for example at the side walls. In this example, areas for soldering are not supposed to be coated by the glass barrier layer 150 and can be protected by photo resist. Furthermore, two of the traces 104 are covered by a solder mask 220 (e.g. comprising barium sulfate, or silicon dioxide) instead. Furthermore, at least a portion of the exposed surface of the electrically insulating layer structure 102 is covered by the glass barrier layer 150. This may bring the advantage of reducing the occurrence of metal, in particular ion migration, between adjacent electrically conductive layer structures 104/210, especially when electrically conductive layer structures 104/210 are in close proximity to each other, for example smaller than 10 μm.

FIG. 9 shows an antenna structure on an electrically insulating layer structure 102 comparable to FIG. 8. In this example, the pad for soldering 210 is (completely) covered by immersion tin 230. Further, in this example, the traces 104 at the right side are covered by the glass barrier layer 150 and further covered by the solder mask 220 on top. In this specific example, the glass barrier layer 150 is configured as a protection layer on the antenna structure and as an adhesion promotion layer between the electrically conductive layer structure 104 and the solder mask 220.

In a specific embodiment, a mixed surface finish is implemented as follows: 1 μm immersion tin (or 5 μm ENIG), 0.1 μm glass barrier layer (nano-glass), and 20 μm solder mask. The glass barrier layer 150 can be arranged under the solder mask 220 or only next to the solder mask 220.

FIG. 10 shows an antenna structure on an electrically insulating layer structure 102 comparable to FIG. 9. Yet, in this example, a cavity 240 is formed in the electrically insulating support base. The sidewalls and the bottom of said cavity 240 are covered by electrically conductive material 104, e.g. plated copper. The electrically conductive material in the cavity 240 is (fully) covered by the glass barrier layer 150 (bottom and sidewalls). By use of the described method, complex shapes of exposed surfaces may be efficiently and void free covered by a glass barrier layer 150 having a thickness smaller than 1 μm.

FIG. 11 shows an antenna structure on an electrically insulating layer structure 102 comparable to FIG. 10. The difference is that the sidewalls of the cavity 240 are not covered by the electrically conductive material 104. Instead, there is an electrically conductive structure (e.g. a copper block) arranged in the center of the cavity 240.

The electrically conductive structure, the (free) bottom of the cavity 240, and the sidewalls of the cavity 240 are covered (coated) by the glass barrier layer 150.

### REFERENCE SIGNS

100 Product, component carrier
102 Electrically insulating layer structure
103 Core layer structure
104 Electrically conductive layer structure
120 Blind hole
121 Through hole
122 Hole bottom
125 Seed layer
126 Via filling, electrically conductive material
130 Photo film
131 Pattern
132 Electrically conductive trace
140 Cavity, embedded component
150 Glass barrier layer
150a First main surface
150b Second main surface
151 First layer
152 Second layer
155 Further glass barrier layer
160 Particles
170 Protection layer
171 Via hole
175 Ti/Cu seed layer
180 Cu seed layer
185 Fine pattern hole/trace
186 Photo resist
190 Plated copper
210 Solder pad
220 Solder mask
230 Immersion tin
240 Antenna cavity

1. A product, comprising:
an electrically insulating layer structure;
an electrically conductive layer structure;
at least one glass barrier layer at least partially sandwiched between the electrically insulating layer structure and the electrically conductive layer structure;
wherein the at least one glass barrier layer comprises two main surfaces, and
wherein the two main surfaces comprise a different adhesion property.

2. The product according to claim 1,
wherein the different adhesion property comprises a different surface tension.

3. The product according to claim 1, further comprising:
functional groups at one or both of the two main surfaces.

4. The product according to claim 1,
wherein the at least one glass barrier layer comprises a thickness in the range of 10 to 600 nm.

5. The product according to claim 1,
wherein the electrically conductive layer structure comprises at least one smooth surface, with a surface roughness Ra of 150 nm or smaller.

6. The product according to claim 1, wherein the at least one glass barrier layer comprises:
a first layer being in direct contact with the electrically conductive layer structure; and/or
a second layer being in direct contact with the electrically insulating layer structure.

7. The product according to claim 1,
wherein one of the two main surfaces of the at least one glass barrier layer and/or the first layer comprises hydrophilic properties; and/or
wherein the other one of the two main surfaces of the at least one glass barrier layer and/or the second layer comprises hydrophilic properties or hydrophobic properties.

8. The product according to claim 1,
wherein one of the two main surfaces of the at least one glass barrier layer and/or the first layer comprises at least one functional group for providing the hydrophilic properties,
wherein the at least one functional group includes one of imine, amine, thiol, thioamide, phosphate, hydroxyl, thiazole, imidazole, acrylate, methacrylate, an alcohol group, 3-hydroxypropyl or 2-hydroxyethyl.

9. The product according to claim 1,
wherein the other one of the two main surfaces of the at least one glass barrier layer and/or the second layer comprises at least one functional group for providing the hydrophobic properties,
wherein the at least one functional group includes one of epoxy, allyl, amine, vinyl, alkyl, anhydride, maleic anhydride, furane, pyrrole, thiophene, and/or a cyclic unsaturated alkene.

10. The product according to claim 1,
wherein the at least one glass barrier layer comprises silicon dioxide (SiO₂), at least one silane, and/or siloxane compound.

11. The product according to claim 1,
wherein the product comprises an adhesion between the electrically conductive layer structure and the at least one glass barrier layer of 40 N/m or more.

12.-14. (canceled)

15. The product according to claim 1,
wherein the at least one glass barrier layer comprises on one main surface a first hydrophilic property and/or functional group which is in direct contact with the electrically conductive layer structure and, on the opposed second main surface, a second hydrophilic property or hydrophobic property and/or functional group, which is different from the first hydrophilic property and/or functional group, which is in direct contact with at least a portion of the electrically insulating layer structure

16. (canceled)

17. The product according to claim 6,
wherein the second layer comprises functional silanes/siloxanes that form a stable bond with the dielectric material of the electrically insulating layer structure and are either hydrophobic or hydrophilic.

18. The product according claim 1,
wherein the at least one glass barrier layer comprises particles that are at least partially embedded in the at least one glass barrier layer.

19.-23. (canceled)

24. The product according to claim 1,
wherein the glass barrier layer is configured to avoid copper migration; and/or
wherein the glass barrier layer comprises self-aligning properties; and/or
wherein the glass barrier layer improves the adhesion between a smooth electrically insulating layer structure and fine line electrically conductive traces.

25.-27. (canceled)

28. The product according to claim 1, further comprising:
two or more surface finish materials, one of them comprising the glass barrier layer.

29. The product according to claim 1, further comprising:
a cavity at least partially covered/coated by the glass barrier layer.

30. A method, comprising:
forming an electrically insulating layer structure;
forming an electrically conductive layer structure; and
forming a glass barrier layer in between the electrically insulating layer structure and the electrically conductive layer structure;
wherein the at least one glass barrier layer comprises two main surfaces, and
wherein the two main surfaces comprise a different adhesion property.

31. The method according to claim 30, wherein forming the glass barrier layer further comprises:
depositing the glass barrier layer on the electrically conductive layer structure, by a plasma process, and/or
providing a glass barrier layer preform that comprises at least one silane and/or siloxane compound, and performing a plasma process, thereby partially oxidizing the glass barrier layer preform to form silicon dioxide from at least part of the silane and/or siloxane compounds, to form the glass barrier layer,

40. A method of using a glass barrier layer, wherein two main surfaces comprise a different adhesion property, for at least one of the following:
as a barrier and/or adhesion promoter between an electrically insulating layer structure and an electrically conductive layer structure;
as a coating for an antenna structure regarding a radio-frequency application and/or a radar application;
as a surface finish.
